(19) United States
(12) Patent Application Publication
(10) Pub. No.: US 2003/0099288 A1
(43) Pub. Date: May 29, 2003

(54) Method and apparatus for detecting and characterizing interference signals in wideband communications channels

(76) Inventors: Vaughn Mower, Bountiful, UT (US); Robert Wright, Sandy, UT (US)

Correspondence Address: Clarence A. Green, Perman & Green, LLP, 425 Post Road, Fairfield, CT, 06430, US

(21) Appl. No.: 09/996,329

(22) Filed: Nov. 28, 2001

(51) Int. Cl. H04L 27/08; H03H 7/40; H03H 7/30; H03K 5/159

(52) U.S. Cl. 375/229; 375/345

(57) ABSTRACT

An inexpensive method and apparatus for detecting and characterizing interference in wideband communication channels obviates the need for expensive prior art Digital Signal Processors (DSPs) and complex custom software, by novelly including with the spectrum analyzer, a burst clamp and an automatic gain control (AGC) circuit upstream of the spectrum analyzer, and a general purpose computer (such as a microcomputer). The burst clamp and AGC circuit (with a time constant τ_{AGC} set much larger than the time constant of the burst interference signal time constant τ_{J}) operate to suppress the monitored signal at the input of the spectrum analyzer during the burst intervals to thereby indicate the presence of interference. The burst clamp and AGC circuit also provide for rapid recovery of the monitored signal after the burst. Connected to the output of the spectrum analyzer, the computer determines the interference type (burst or continuous wave (CW)).

### FIELD OF THE INVENTION

The present invention broadly relates to communications systems that may be the target of jamming signals. More particularly, the present invention relates to the detection and characterization of interference signals in communication channels.

### BACKGROUND OF THE RELATED ART

In communication systems, electronic equipment such as receivers, transceivers and the like, require the receipt of conforming signals for proper operation. In hostile environments, such as may be encountered in military operations, communication systems (whether involving communication links, RADAR, or others) often encounter “jamming.” Jamming is the deliberate generation or reflection of electromagnetic radiation by one, with the intent to impair the operation of the electronic equipment of another. Some jamming operations are accomplished by the sustained use of “jammers” to spew burst or continuous wave (CW) interference signals.

When electromagnetic interference signals are received by a communication system, the system must be able to distinguish between legitimate signals and jamming signals. Otherwise, problems can result ranging from the inadvertent incorporation of erroneous information, to overload, to inoperability. For example, the presence of jamming in an information signal communication channel might require that the data rate is reduced in order to achieve maintain an acceptable error rate.

Prior art methods exist for detecting and characterizing electromagnetic radiation received by a communication system so that interference signals can be appropriately handled, including the suppression of legitimate signals until the interference has passed, and modifying signals to reduce or eliminate the impact of jamming, such as lowering the transmission data rate of signals while jamming persists. Unfortunately, current methods require, along with a spectrum analyzer, the use of expensive Digital Signal Processors (DSPs) and complex, custom software needed to function with the eccentricities of the particular communication system.

Ergo, what are needed are an inexpensive method and apparatus for detecting and characterizing interference electromagnetic radiation in a communication channel.

### SUMMARY OF THE INVENTION

In view of the above-identified problems and limitations of the prior art, the present invention provides a system for detecting and characterizing burst or continuous wave jamming interference in a communication channel adapted to receive a monitored signal. The system at least includes a spectrum analyzer adapted to spectrally analyze an input signal, and a burst clamp coupled at its output to the spectrum analyzer, the burst clamp activated to clamp a received signal at a predetermined level when a predetermined threshold in the received signal is reached. The system also at least includes an automatic gain control (AGC) in a feedback loop coupled to the input of the burst clamp and coupled to the output of the burst clamp, and a computer coupled to the output of the spectrum analyzer, adapted to characterize the type of interference upon activation of the burst clamp.

The present invention also provides a method for detecting and characterizing burst or continuous wave jamming interference in a communication channel adapted to receive a monitored signal. The method at least includes the steps of, via a spectrum analyzer, spectrally analyzing an input signal, and via a burst clamp coupled at its output to the spectrum analyzer, activating the burst clamp activated to clamp a received signal at a predetermined level when a predetermined threshold in the received signal is reached. The method also at least includes the steps of, via an AGC in a feedback loop coupled to the input of the burst clamp and coupled to the output of the burst clamp, automatically substantially stabilizing the gain of a received signal to a predetermined level, and via a computer coupled to the output of the spectrum analyzer, characterizing the type of interference upon activation of the burst clamp.

The present invention is described in detail below, with reference to the drawing.

### BRIEF DESCRIPTION OF THE DRAWING

Features and advantages of the present invention will become apparent to those skilled in the art from the following description with reference to the drawing, in which:

FIG. 1—the sole FIGURE—is a general schematic block diagram of the present-inventive interference detection and characterization circuit.

### DETAILED DESCRIPTION OF THE PREFERRED EMBODIMENTS

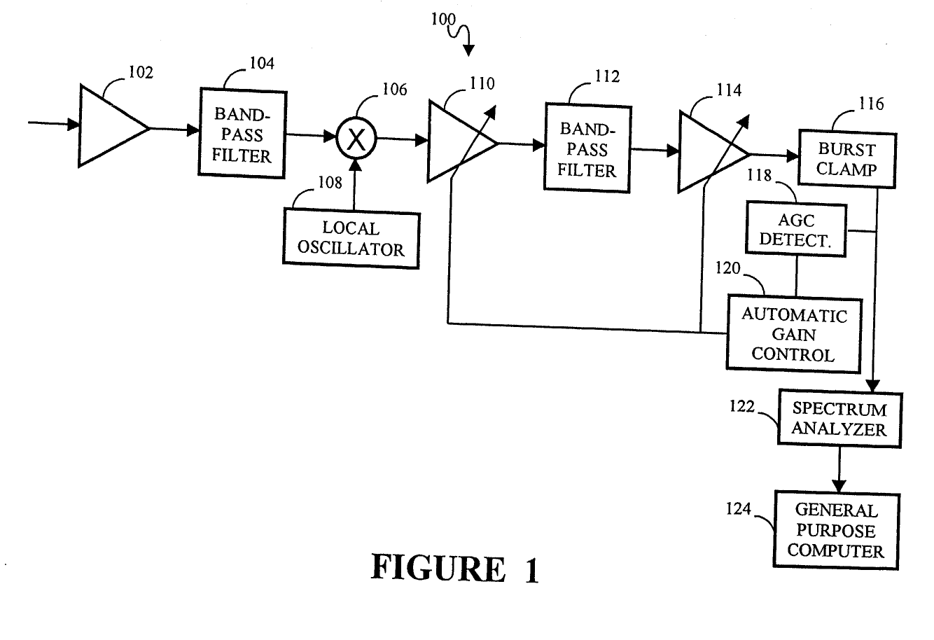

FIG. 1 is a general schematic block diagram of the present-inventive interference detection and characterization circuit 100—also referred to as a link sensor. The link sensor 100 monitors electromagnetic (EM) radiation at a predetermined frequency or frequencies. The predetermined frequencies are those which are to be used in a communication link where integrity of signals is important. Those skilled in the art will appreciate that the link sensor 100 can be used proactively before communication, so that if jamming is detected, the communication link operator can forego communication at the monitored frequency, or cause the communication link equipment to modify signal formats (such as reducing the data rate) to reduce or eliminate the effectiveness of the jamming. The communication channel of interest can also be periodically or perpetually monitored for jamming while the communication link is operational.

In the preferred embodiment, the link sensor 100 monitors one particular communication channel for jamming. However, given the teachings in this Letters Patent, the link sensor 100 can be modified to contemporaneously monitor several communication channels.

The link sensor 100 receives EM radiation (via an antenna) at the input of a low noise amplifier 102 that produces approximately 20 decibels (dB) of gain in the preferred embodiment. An image (band pass) filter 104 filters the output of the amplifier 102. The output of the image filter 104 and that of a local oscillator 108 is combined by a mixer 106 to produce an intermediate frequency (IF) signal, as will be appreciated by those skilled in the art.

The signal then passes through a first variable amplifier 110, followed by another band pass filter 112 with high Q and thus narrow band characteristics, and a second variable amplifier 114. A burst clamp 116 reduces the base band output to near zero when it encounters an input signal above a set level. A feedback loop between the burst clamp 116 and amplifier 110 contains an automatic gain control detector 118, followed by an automatic gain control (AGC) 120. The AGC 120 monitors the average power level received from the burst clamp, and attempts to adjust the variable amplifiers 110 and 114 to keep them in the linear operation range to avoid signal distortion. The AGC detector 118 is a typical rectification and filtering circuit.

In the preferred embodiment, the level for activating and triggering the burst clamp is 2 dB above the nominal AGC set point or average power level. As a novel feature of the present invention, the activation of the burst clamp 116 is a direct indication of the presence of interference.

The burst clamp 116 also sends its output to a spectrum analyzer 120 to spectrally analyze received signals in a manner known in the art. A matter of design choice, the spectrum analyzer 120 can be any suitable one from among those commercially available. The output of the spectrum analyzer 122 is sent to a general processor or computer 124. While the computer 124 is a general purpose one in the preferred embodiment, such as a microcomputer, it may also be a special purpose device without departing from the scope of the present invention. The computer 124 is responsible for determining, during clamping episodes, the nature of the interference. The time constant τ_{AGC} of the AGC is sufficiently large compared to the time constant τ_{J} of received jamming signals that the trace of the spectrum analyzer 122 abruptly decreases when an interference burst is received, and abruptly increases when the interference burst has passed.

The computer 124 characterizes the interference by measuring the burst pulse width, the burst pulse repetition rate, the burst pulse duty cycle, and other attributes of the burst interference. Typical characterization of interference includes determining it to be of the burst variety or of the continuous wave variety. The detection of interference by the link sensor can be output to an automatic communication link control system (not shown) for the automatic adjustment or cessation of communication signals during the presence of jamming. Alternatively, the output of the computer can be interpreted by human operators who can adjust the communication link accordingly.

In the preferred embodiment, the sweep time of the spectrum analyzer 122 is a limiting factor in the minimum pulse width of interference bursts characterizable by the link sensor. Shorter burst durations require shorter spectrum analyzer sweep times, as will be appreciated by those skilled in the art. The present-inventive link sensor 100 is also able to detect multiple jamming signals. This can be accomplished by placing the spectrum analyzer on maximum hold, and performing several scans during the hold, so that jamming signals appear as spikes or bursts significantly above the level of the rest of the spectrum.

Variations and modifications of the present invention are possible, given the above description. However, all variations and modifications which are obvious to those skilled in the art to which the present invention pertains are considered to be within the scope of the protection granted by this Letters Patent.

For example, while the preferred embodiment of the present invention is well-suited for wide band communication channels using typical commercially available spectrum analyzers, its efficacy may be limited with respect to narrow band communication channels because the spectrum analyzer sweep speed may be inadequate.

It should also be understood that the present-inventive link sensor and method are operational with multiple types of communication signals, including spread spectrum.

What is claimed is:

1. A system for detecting and characterizing burst or continuous wave jamming interference in a communication channel adapted to receive a monitored signal, said system comprising:
a spectrum analyzer adapted to spectrally analyze an input signal;
a burst clamp coupled at its output to said spectrum analyzer, said burst clamp activated to clamp a received signal at a predetermined level when a predetermined threshold in said received signal is reached;
an automatic gain control (AGC) in a feedback loop coupled to the input of said burst clamp and coupled to the output of said burst clamp; and
a computer coupled to the output of said spectrum analyzer, adapted to characterize the type of interference upon activation of said burst clamp.

2. The system in claim 1, wherein the time constant of said AGC is substantially greater than the time constant of jamming interference signals expected to be received by said communication channel.

3. The system in claim 1, wherein said computer is further adapted to determine burst interference durations.

4. The system in claim 1, wherein said computer is further adapted to determine burst interference repetition rates.

5. The system in claim 1, wherein said computer is further adapted to determine burst interference duty cycles.

6. The system in claim 1, wherein said burst clamp and AGC are adapted to, in response to said computer, rapidly restore said monitored signal after the passage of an interference burst.

7. A method for detecting and characterizing burst or continuous wave jamming interference in a communication channel adapted to receive a monitored signal, said method comprising the steps of:
via a spectrum analyzer, spectrally analyzing an input signal;
via a burst clamp coupled at its output to said spectrum analyzer, activating said burst clamp activated to clamp a received signal at a predetermined level when a predetermined threshold in said received signal is reached;
via an automatic gain control (AGC) in a feedback loop coupled to the input of said burst clamp and coupled to the output of said burst clamp, automatically substantially stabilizing the gain of a received signal to a predetermined level; and
via a computer coupled to the output of said spectrum analyzer, characterizing the type of interference upon activation of said burst clamp.

8. The method in claim 7, wherein the time constant of said AGC is substantially greater than the time constant of jamming interference signals expected to be received by said communication channel.

9. The method in claim 7, further comprising the step of, via said computer, determining burst interference durations.

10. The method in claim 7, further comprising the step of, via said computer, determining burst interference repetition rates.

11. The method in claim 7, further comprising the step of, via said computer, determining burst interference duty cycles.

12. The method in claim 7, further comprising the step of, via said burst clamp and AGC in response to said computer, rapidly restoring said monitored signal after the passage of an interference burst.
